(19) United States
(12) Patent Application Publication
(10) Pub. No.: US 2007/0281455 A1
(43) Pub. Date: Dec. 6, 2007

(54) Semiconductor device with bulb recess and saddle fin and method of manufacturing the same

(75) Inventor: Kwang-Ok Kim, Kyoungki-do (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX Semiconductor Inc.

(21) Appl. No.: 11/646,301

(22) Filed: Dec. 28, 2006

(30) Foreign Application Priority Data
Jun. 1, 2006 (KR) 10-2006-0049436

(51) Int. Cl. H01L 21/3205

(52) U.S. Cl. 438/589

(57) ABSTRACT

A semiconductor device includes an active region, a bulb recess with a certain depth formed in a channel-forming region of the active region, a device isolation structure encompassing the active region, wherein the device isolation structure has a line-shaped opening such that a surface of the device isolation structure is lower than the bottom of the bulb recess and a portion of the active region is protruded more than the device isolation structure in the shape of a saddle fin, a gate insulating layer formed over the device isolation structure exposed by the opening and the active region including the bulb recess, and a gate electrode formed over the gate insulating layer, the gate electrode filled in the bulb recess and covering the device isolation structure exposed by the opening.

### CROSS-REFERENCE TO RELATED APPLICATION

The present application contains subject matter related to the Korean patent application No. KR 2006-0049436, filed in the Korean Patent Office on Jun. 1, 2006, the entire contents of which being incorporated herein by reference.

### TECHNICAL FIELD

The present invention relates to a method of manufacturing a semiconductor device, and more particularly, to a semiconductor device with a bulb recess and a saddle fin and a method of manufacturing the same.

### BACKGROUND

As a semiconductor device is ultra-highly integrated, it is difficult to sufficiently secure refresh characteristics of the device according to a typical method of forming a planar gate on a flat active region, because junction leakage is caused by the increase of electric field with the decrease of a gate channel length and the increase of an implant doping concentration.

In order to overcome the above limitation, a recess gate process is performed in such a way that an active region is patterned so as to form a recess pattern therein (this is referred to as silicon recess process) and thereafter, a conductive material is filled into the recess pattern to thereby form a recess gate. This recess gate process makes it possible to increase the gate channel length and decrease the implant doping concentration so that the refresh characteristics of the device can be enhanced accordingly.

FIG. 1 is a cross-sectional view of a gate stack structure using the silicon recess process according to the typical method. A recess 12 is formed on a certain region of a substrate 11 where a channel will be formed (hereinafter, referred to as a channel-forming region in brief) through the silicon recess process. A gate oxide layer 13 is formed on the surface of the substrate 11 having the recess 12, and a gate stack is formed on the gate oxide layer 13, wherein the gate stack is configured with a polysilicon 14, a metal-based electrode 15 formed of tungsten silicide (WSi) or tungsten (W), and a gate hard mask 16, which are stacked in sequence.

However, the semiconductor device having the gate stack structure of FIG. 1 still has a limitation that a refresh time characteristic becomes poor when the device is miniaturized into the smaller transistor. To address the above limitation, a bulb recess structure has been proposed recently.

FIG. 2 is a cross-sectional view of a gate stack structure having a bulb-shaped recess according to the typical method. A bulb-shaped recess 22 (hereinafter, referred to as the bulb recess) is provided in a certain region of a substrate 21, i.e., a channel-forming region. Thereafter, a gate oxide layer 23 is formed on a surface of the substrate 21 including the bulb recess 22, and a gate stack is then formed on the gate oxide layer 23, wherein the gate stack is configured with a polysilicon 24, a metal-based electrode 25 formed of tungsten silicide (WSi) or tungsten (W), and a gate hard mask 26, which are stacked in sequence.

When applying the bulb recess structure of FIG. 2 to the semiconductor device, it may be possible to improve the limitation of the refresh time. However, there occurs another limitation that the current driving capability is gradually degraded as the device becomes smaller.

### SUMMARY

An embodiment of the present invention relates to a semiconductor device capable of securing a current driving capability as well as improving a refresh time characteristic.

In accordance with an aspect of the present invention, there is provided a semiconductor device, including: an active region; a bulb recess with a certain depth formed in a channel-forming region of the active region; a device isolation structure encompassing the active region, wherein the device isolation structure has a line-shaped opening such that a surface of the device isolation structure is lower than the bottom of the bulb recess and a portion of the active region is protruded more than the device isolation structure in the shape of a saddle fin; a gate insulating layer formed over the device isolation structure exposed by the opening and the active region including the bulb recess; and a gate electrode formed over the gate insulating layer, the gate electrode filled in the bulb recess and covering the device isolation structure exposed by the opening.

In accordance with another aspect of the present invention, there is provided method of manufacturing a semiconductor device, including: forming a device isolation structure in a substrate to define an active region; etching a channel-forming region of the active region to a certain depth to form a bulb recess; selectively etching the device isolation structure to form a line-shaped opening such that a surface of the device isolation structure is lower than the bottom of the bulb recess and a portion of the active region is protruded more than the device isolation structure in the shape of a saddle fin; forming a gate insulating layer over the surface of the resultant structure including the bulb recess and the devices isolation layer exposed by the opening; and forming a gate electrode over the gate insulating layer such that the gate electrode is filled into the bulb recess and covers the device isolation structure exposed by the opening.

In accordance with still another aspect of the present invention, there is provided method of manufacturing a semiconductor device, including: forming a device isolation structure in a substrate to define an active region; selectively etching the device isolation structure to form an opening exposing either side of a channel-forming region of the active region, wherein a bottom of the opening is lower than the surface of the active region; etching the channel-forming region of the active region higher than the bottom surface of the opening to form a bulb recess having a saddle fin structure; forming a gate insulating layer over the surface of the resultant structure including the bulb recess; and forming a gate electrode over the gate insulating layer such that the gate electrode is filled into the bulb recess and covers the device isolation structure exposed by the opening.

### BRIEF DESCRIPTION OF THE DRAWINGS

FIG. 1 is a cross-sectional view of a gate stack structure using silicon recess process according to the typical method;

FIG. 2 is a cross-sectional view of a gate stack structure having a bulb recess according to the typical method;

FIGS. 3A to 3D are cross-sectional views illustrating a method of manufacturing a semiconductor device in accordance with a first embodiment of the present invention;

FIG. 4 is a partially sectional perspective view taken along a major axis direction, illustrating the structure of the semiconductor device in accordance with the first embodiment of the present invention; and

FIGS. 5A to 5D are cross-sectional views illustrating a method of manufacturing a semiconductor device in accordance with a second embodiment of the present invention.

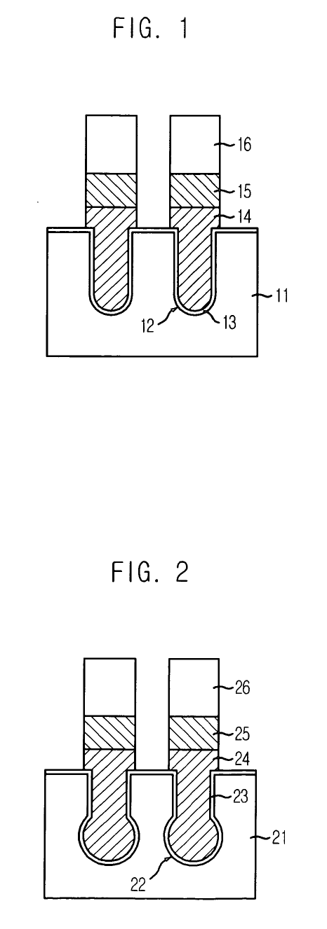

### DETAILED DESCRIPTION

A semiconductor device with a bulb recess and a saddle fin and a method of manufacturing the same in accordance with exemplary embodiments of the present invention will be described in detail with reference to the accompanying drawings.

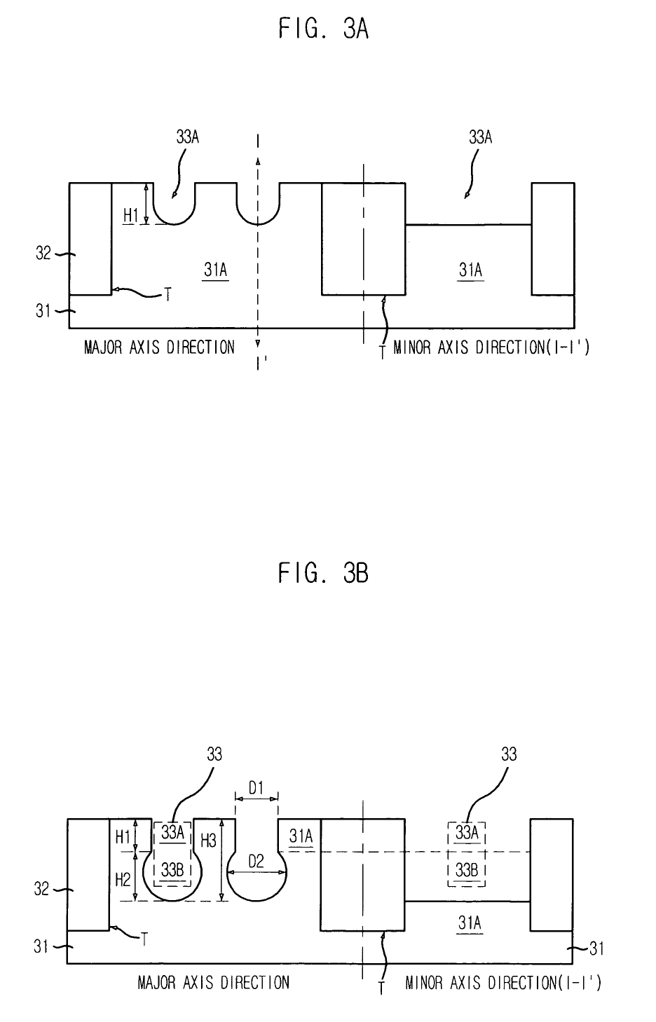

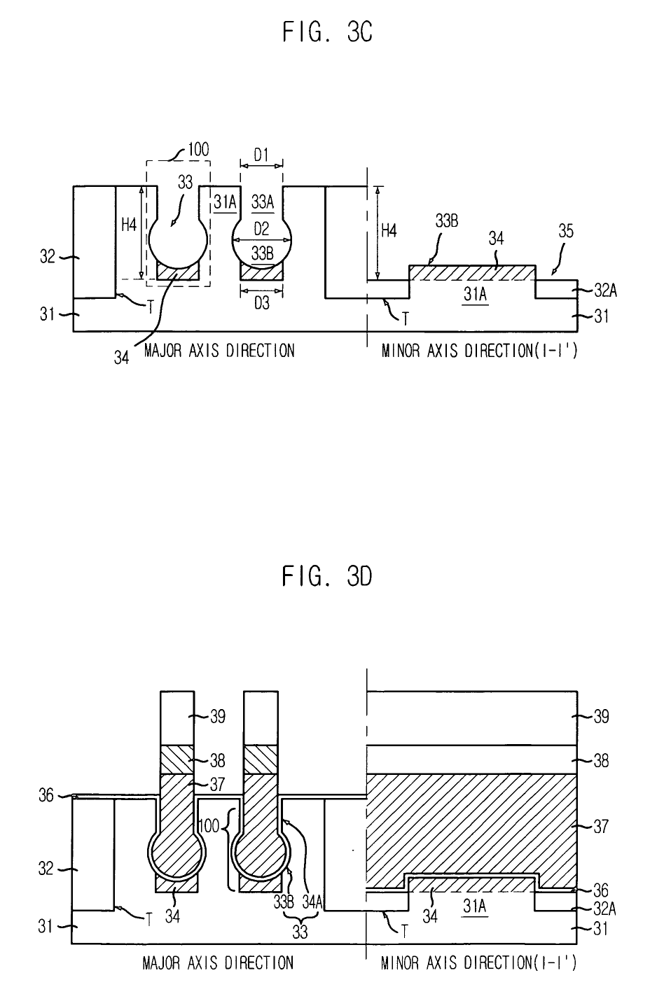

FIGS. 3A to 3D are cross-sectional views illustrating a method of manufacturing a semiconductor device in accordance with a first embodiment of the present invention. Hereinafter, a left portion of an alternated long and short dash line is a cross-sectional view taken along a major axis direction of an active region, and a right portion of the alternated long and short dash line is a cross-sectional view taken along a minor axis direction of the active region, e.g., particularly a line I-I′.

Referring to FIGS. 3A and 3B, a device isolation structure 32 is formed such that the device isolation structure 32 is filled into a trench T in a substrate 31 using shallow trench isolation (STI) technique. By means of the device isolation structure 32, an active region 31A is defined in the substrate 31.

Subsequently, the active region 31A is etched to a certain depth through silicon recess etching process so as to form a bulb recess 33. Here, the bulb recess 33 is formed by etching a certain region of the active region 31A where a gate channel will be formed in the active region 31A. Hereinafter, the certain region of the active region 31A where a channel will be formed is referred to as the channel-forming region in brief.

A method of forming the bulb recess 33 begins with etching the active region 31A to a first depth H1 to thereby form a neck pattern 33A of which an etching profile is a vertical shape. Thereafter, an isotropic etching is performed so that a bottom surface of the neck pattern 33A becomes a round profile. Accordingly, there is formed a ball pattern 33B having a second depth H2, wherein the ball pattern 33B is communicated with the neck pattern 33A. That is, the bulb recess 33 is configured with the neck pattern 33A and the ball pattern 33B so that a final depth of the bulb recess 33 is H3. Herein, the final depth H3 of the bulb recess 33 may be shallower than the depth of the device isolation structure 32 in terms of leakage current. In addition, the bulb recess 33 is formed such that the width D2 of the ball pattern 33B is greater than the width D1 of the neck pattern 33A, which results in increasing the channel length more.

The etching process of forming the bulb recess 33 will be more fully illustrated below. First, chlorine (Cl₂) gas, hydrogen bromide (HBr) gas or mixed gas thereof may be used as an etching gas in forming the neck pattern 33A. Next, the isotropic etching is carried out to form the ball pattern 33B using a mixed gas of carbon tetrafluoride/oxygen (CF₄/O₂) or a mixed gas of Cl₂/HBr/sulfur hexaflouride (SF₆)/O₂.

Meanwhile, a spacer having a thickness of approximately 250 Å may be preformed on sidewalls of the neck pattern 33A using a nitride so as to prevent the sidewalls of the neck pattern 33A from being damaged when forming the ball pattern 33B.

The bulb recess 33 is formed by etching the channel-forming region of the active region 31A, and both ends of the bulb recess 33 are adjacent to the device isolation structure 32, which is well understood from the sectional view of FIG. 3B taken along the minor axis direction. That is, as it is shown in the sectional view taken along the minor axis direction, both the ends of the bulb recess 33 is in contact with the device isolation structure 32, and the bottom surface of the bulb recess 33 is shallower than the bottom surface of the trench T into which the device isolation structure 32 is filled.

Referring to FIG. 3C, the device isolation structure 32 in contact with the bulb recess 33 is etched to a certain depth to thereby form a saddle-shaped fin 34 (hereinafter, referred to as the saddle fin). That is, the device isolation structure 32 in contact with both the ends of the bulb recess 33 is etched to the certain depth so as to form a line-shaped opening 35. Accordingly, the active region 31A under the ball pattern 33B of the bulb recess 33 is more protruded in the shape of a fin than a patterned device isolation structure 32A. Specifically, because the surface of the device isolation structure 32 becomes lower than the bottom surface of the ball pattern 33B of the bulb recess 33 in virtue of the line-shaped opening 35, the active region 31A under the ball pattern 33B is more upwardly protruded than the surface of the patterned device isolation structure 32A. Herein, it is shown in the sectional view of FIG. 3C taken along the major axis direction that the saddle fin 34 is disposed under the bottom surface of the ball pattern 33B of the bulb recess 33, whereas it is shown in the sectional view of FIG. 3C taken along the minor axis direction that saddle fin 34 is protruded upward due to the line-shaped opening 35.

The etching of the device isolation structure 32 is performed by making use of the mask which has been used in forming the neck pattern 33A, and particularly the device isolation structure 32 is etched under the etching condition such as satisfactory etch selectivity with respect to silicon in order to prevent etch damage of the bulb recess 33. Thus, the width D3 of the saddle fin 34 is substantially the same as the width D1 of the neck pattern 33A but is smaller than the width D2 of the ball pattern 33B. Meanwhile, it is noticed that a depth difference between the top surface of the saddle fin 34 and the bottom surface of the patterned device isolation structure 32A should be approximately 150 Å or greater, e.g., approximately 150 Å to approximately 300 Å.

By forming the saddle fin 34 through a series of processes as described above, there is obtained a bulb saddle fin (BS-fin) structure configured with the bulb recess 33 and the saddle fin 34. Herein, the BS-fin is denoted as a reference numeral 100 in the drawings, of which the depth is H4.

As described above, by forming the BS-fin 100 having the bulb recess 33 and the saddle fin 34 disposed thereunder, it is possible to elongate the channel length longer than the case of employing the bulb recess structure only. Besides, the bulb recess 33 with superior refresh time characteristic and the saddle fin 34 with satisfactory current driving capability are combined together in the present invention to thereby improve the current driving capability as well as the refresh time characteristic.

Referring to FIG. 3D, after forming a gate insulating layer 36 on the surface of the resultant structure including the BS-fin 100, a polysilicon 37 is deposited on the gate insulating layer 36 until the BS-fin 100 is fully filled with the polysilicon 37. At this time, since there may exist surface waviness caused by the BS-fin 100 when depositing the polysilicon 37, a planarization process may be additionally performed through chemical mechanical polishing (CMP) process or the like.

Subsequently, after forming a metal-based electrode 38 formed of tungsten silicide (WSi) or tungsten (W), and a gate hard mask 39 on the polysilicon 37 in sequence, a gate patterning process is performed using the gate mask.

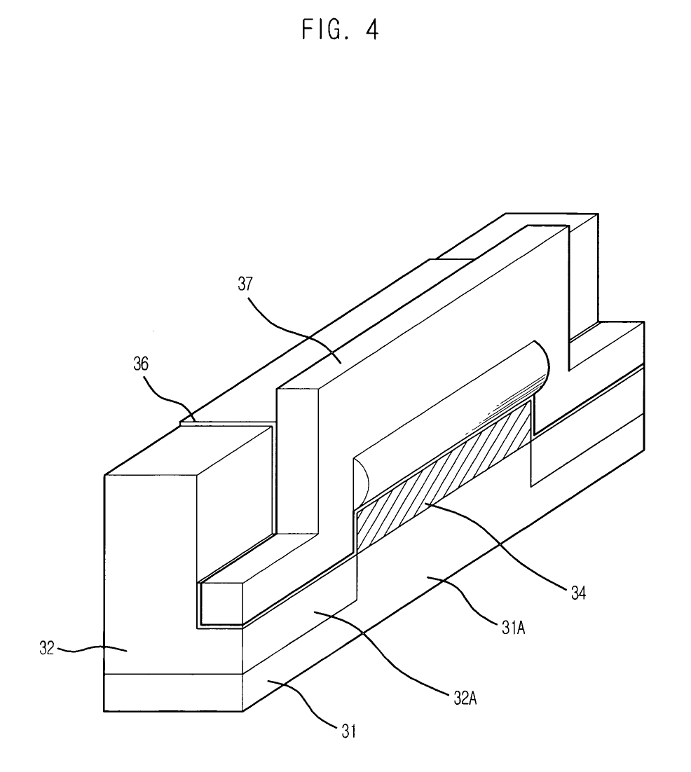

FIG. 4 is a partially sectional perspective view taken along the major axis direction, illustrating the structure of the semiconductor device in accordance with the first embodiment of the present invention. Only the polysilicon 37 is depicted in the gate stack structure.

It is understood that the polysilicon 37 is formed on the surface of the patterned device isolation structure 32A that is etched to the certain depth. The gate insulating layer 36 and the polysilicon 37 are also formed on both sidewalls of the saddle fin 34. Since the polysilicon 37 has such a shape that the polysilicon 37 is filled into the bulb recess 33, the polysilicon 37 has a rounded protrusion like a bulb partially due to the ball pattern 33B of the bulb recess 33. Herein, like reference numerals denote like elements so that reference numerals not depicted in FIG. 4 may be referred to FIGS. 3A to 3D.

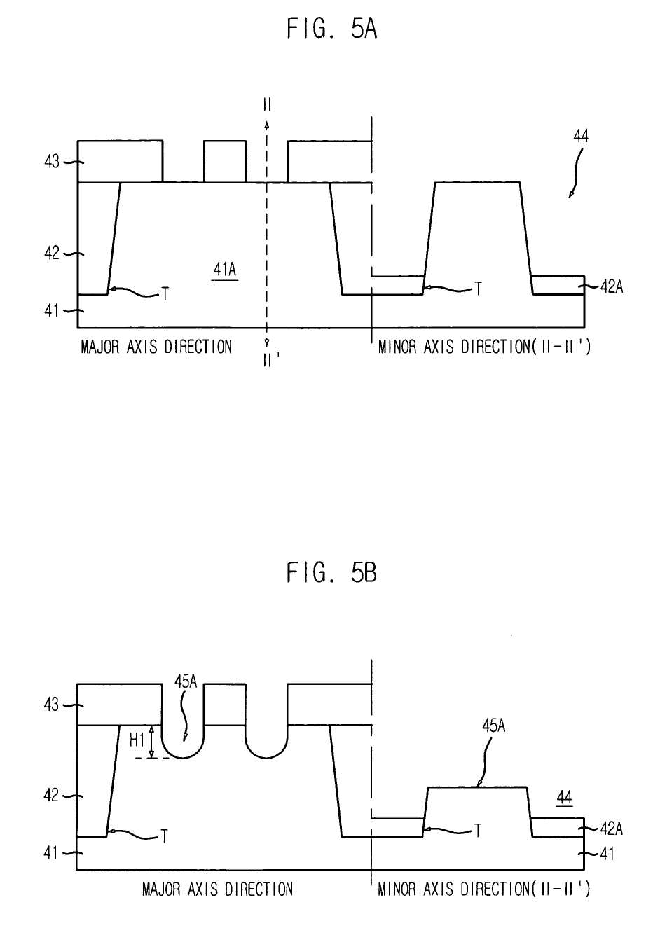

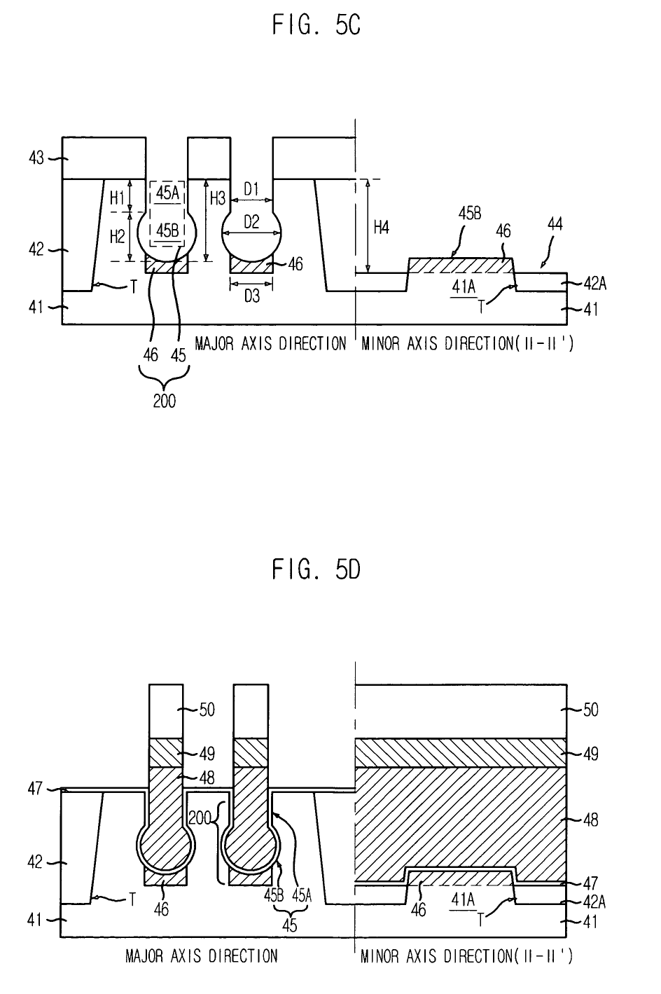

FIGS. 5A to 5D are cross-sectional views illustrating a method of manufacturing a semiconductor device in accordance with a second embodiment of the present invention. Hereinafter, a left portion of an alternated long and short dash line is a cross-sectional view taken along a major axis direction, and a right portion of the alternated long and short dash line is a cross-sectional view taken along a minor axis direction, e.g., particularly a line II-II′.

Referring to FIG. 5A, a device isolation structure 42 is formed in a substrate 41 using STI technique so that an active region 41A is defined by the device isolation structure 42.

Meanwhile, the device isolation structure 42 is filled into a trench T having a slope etch profile instead of vertical profile, and thus the device isolation structure 42 also has sidewalls of the slope profile. Thus, if the silicon recess process is performed first in case that the device isolation structure 42 has the sidewalls of the slope profile, there may occur a large horn due to the slope profile so that it is difficult to form a bulb recess in a post-up process.

Therefore, in the second embodiment of the present invention, the device isolation structure 42 is patterned to a line shape in advance, and thereafter the silicon recess etching process is performed. In detail, a mask 43 is formed on the surface using a photoresist layer, wherein the mask 43 opens a channel-forming region of the active region and the top surface of the device isolation structure 42 adjacent to the channel-forming region. Thereafter, the device isolation structure 42 not shielded by the mask 43 is etched to a certain depth using the mask as an etch barrier, thereby forming an opening 44. Herein, the device isolation structure 42 is etched under the etching condition such as satisfactory etch selectivity with respect to silicon in order to prevent etch damage of the active region 41A.

Meanwhile, the photoresist layer may be singly used as the mask 43 or a hard mask may be used as the mask 43 alternatively. Herein, the opening 44 can be seen only in the sectional view taken along the minor axis direction II-II′, and a patterned device isolation structure 42A remaining under the opening 44 has smaller thickness than before.

Referring to FIGS. 5B and 5C, the exposed channel-forming region of the active region 41A is etched by silicon recess etching process using the mask 43 used in etching the device isolation structure 42. A method of forming a bulb recess 45 begins with etching the active region 41A to a first depth H1 to thereby form a neck pattern 45A of which an etching profile is a vertical shape. Thereafter, an isotropic etching is performed so that a bottom surface of the neck pattern 45A becomes a round profile. Accordingly, there is formed a ball pattern 45B having a second depth H2, wherein the ball pattern 45B is communicated with the neck pattern 45A. That is, the bulb recess 45 is configured with the neck pattern 45A and the ball pattern 45B so that a final depth of the bulb recess 45 is H3. Herein, the final depth H3 of the bulb recess 45 may be shallower than the depth of the device isolation structure 42 in terms of leakage current. In addition, the bulb recess 45 is formed such that the width D2 of the ball pattern 45B is greater than the width D1 of the neck pattern 45A, which results in increasing the channel length more.

The etching process of forming the bulb recess 45 will be more fully illustrated below. First, chlorine (Cl₂) gas, hydrogen bromide (HBr) gas or mixed gas thereof may be used as an etching gas in forming the neck pattern 45A. Next, the isotropic etching is carried out to form the ball pattern 45B using a mixed gas of CF₄/O₂ or a mixed gas of Cl₂/HBr/SF₆/O₂.

Meanwhile, a spacer having a thickness of approximately 250 Å may be preformed on sidewalls of the neck pattern 45A using a nitride in forming the ball pattern 45B so as to prevent the sidewalls of the neck pattern 45A from being damaged in forming the ball pattern 45B.

The bulb recess 45 is formed by etching the channel-forming region of the active region 41A, and both ends of the bulb recess 45 are adjacent to the patterned device isolation structure 42A. That is, as it is shown in the sectional view taken along the minor axis direction, both the ends of the bulb recess 45 is in contact with the patterned device isolation structure 42A, and the bottom surface of the bulb recess 45 is shallower than the bottom surface of the trench T into which the device isolation structure 42 is filled.

By forming the bulb recess 45 as above, the saddle fin 46 is formed higher than the surface of the patterned device isolation structure 42A. Here, the height of the saddle fin 46 more protruded than the patterned device isolation structure 42A is at least approximately 150 Å, i.e., in range of approximately 150 Å to approximately 300 Å. Thus, the depth difference between the saddle fin 46 and the patterned device isolation structure 42A should be 150 Å or greater.

That is, since the patterned device isolation structure 42A in contact with both the ends of the bulb recess 45 is etched in advance, the bottom surface of the ball pattern 45B of the bulb recess 45 is protruded in the shape of a fin. Specifically, when etching the active region under the opening 44 to form the bulb recess 45 after forming the opening 44 in advance, the bottom surface of the ball pattern 45B becomes higher than the surface of the patterned device isolation structure 42A so that the bottom surface of the ball pattern 45B is protruded more than the surface of the patterned device isolation structure 42A. Herein, it is shown in the sectional view taken along the major axis direction such that the saddle fin 46 is disposed under the bottom surface of the ball pattern 45B of the bulb recess 45, whereas it is shown in the sectional view taken along the minor axis direction such that the saddle fin 46 is protruded more than the patterned device isolation structure 42A.

Meanwhile, in order to form the saddle fin 46, the etching process is performed under the etching condition such as satisfactory etch selectivity with respect to the device isolation structure 42 formed of oxide, using the mask 43. The width D3 of the saddle fin 46 is substantially the same as the width D1 of the neck pattern 45A but smaller than the width D2 of the ball pattern 45B.

By forming the saddle fin 46 through a series of processes as described above, there is obtained a bulb saddle fin (BS-fin) structure configured with the bulb recess 45 and the saddle fin 46. Herein, the BS-fin is denoted as a reference numeral 200 in the drawings, of which the depth is H4.

As described above, by forming the BS-fin 200 having the bulb recess 45 and the saddle fin 46 disposed thereunder, it is possible to elongate the channel length longer than the case of employing the bulb recess structure only. Besides, the bulb recess 45 with superior refresh time characteristic and the saddle fin 46 with satisfactory current driving capability are combined together in the present invention to thereby improve the current driving capability as well as the refresh time characteristic.

Referring to FIG. 5D, after forming a gate insulating layer 47 on the surface of the resultant structure including the BS-fin 200, a polysilicon 48 is deposited on the gate insulating layer 47 until the BS-fin 200 is fully filled with the polysilicon 48. At this time, since there may exist surface waviness caused by the BS-fin 200 in depositing the polysilicon 48, a planarization process may be additionally performed through CMP process or the like.

Subsequently, after forming a metal-based electrode 49 formed of tungsten silicide (WSi) or tungsten (W), and a gate hard mask 50 on the polysilicon 48 in sequence, a gate patterning process is performed using the gate mask.

In the second embodiment as described above, the etch profile of the trench T into which the device isolation structure 42 is filled has the shape of a slope. In the second embodiment, the opening 44 is preformed for protruding the saddle fin structure by etching the device isolation structure 42 to a certain depth before forming the bulb recess 45. Accordingly, it is possible to prevent the occurrence of the horn caused by the trench T having the slope profile in the etching process of forming the bulb recess 45.

In accordance with the embodiments, the present invention employs the saddle fin as well as the bulb recess for securing sufficient refresh and performance of a transistor. Therefore, it is possible to improve the refresh time characteristic resulted from the advantage of the bulb recess and further secure the current driving capability resulted from the advantage of the saddle fin.

As described above, the present invention provides an advantageous effect of securing the current driving capability as well the refresh time characteristic by forming the BS-fin configured with the bulb recess and the saddle fin.

While the present invention has been described with respect to some embodiments, it will be apparent to those skilled in the art that various changes and modifications may be made without departing from the spirit and scope of the invention as defined in the following claims.

What is claimed is:

1. A semiconductor device, comprising:
an active region;
a bulb recess with a certain depth formed in a channel-forming region of the active region;
a device isolation structure encompassing the active region, wherein the device isolation structure has a line-shaped opening such that a surface of the device isolation structure is lower than the bottom of the bulb recess and a portion of the active region is protruded more than the device isolation structure in the shape of a saddle fin;
a gate insulating layer formed over the device isolation structure exposed by the opening and the active region including the bulb recess; and
a gate electrode formed over the gate insulating layer, the gate electrode filled in the bulb recess and covering the device isolation structure exposed by the opening.

2. The semiconductor device of claim 1, wherein the bulb recess comprises:
a neck pattern of a vertical profile having a first width; and
a ball pattern of a round profile having a second width greater than the first width.

3. The semiconductor device of claim 2, wherein the width of the neck pattern of the bulb recess is substantially the same as the width of the opening of the device isolation structure.

4. The semiconductor device of claim 3, wherein a height of the active region which is protruded more than the device isolation structure in the shape of the saddle fin is at least approximately 150 Å.

5. A method of manufacturing a semiconductor device, the method comprising:
forming a device isolation structure in a substrate to define an active region;
etching a channel-forming region of the active region to a certain depth to form a bulb recess;
selectively etching the device isolation structure to form a line-shaped opening such that a surface of the device isolation structure is lower than the bottom of the bulb recess and a portion of the active region is protruded more than the device isolation structure in the shape of a saddle fin;
forming a gate insulating layer over the surface of the resultant structure including the bulb recess and the devices isolation layer exposed by the opening; and
forming a gate electrode over the gate insulating layer such that the gate electrode is filled into the bulb recess and covers the device isolation structure exposed by the opening.

6. The method of claim 5, wherein selectively etching further comprises:
forming a mask that opens an inlet of the bulb recess, and opens the device isolation structure adjacent to the bulb recess in a line shape; and
selectively etching the device isolation structure using the mask as an etch barrier such that the top surface of the device isolation structure is lower than the bottom surface of the bulb recess.

7. The method of claim 6, wherein forming a mask further comprises, forming a mask that opens an inlet of the bulb recess to a width and opens the device isolation structure adjacent to the bulb recess in a line shape to substantially the same width.

8. The method of claim 6, wherein forming a mask further comprises, forming a mask that opens an inlet of the bulb recess, and opens the etched depth of the device isolation structure deeper than the bottom surface of the bulb recess by at least 150 Å.

9. A method of manufacturing a semiconductor device, the method comprising:
forming a device isolation structure in a substrate to define an active region;
selectively etching the device isolation structure to form an opening exposing either side of a channel-forming region of the active region, wherein a bottom of the opening is lower than the surface of the active region;
etching the channel-forming region of the active region higher than the bottom surface of the opening to form a bulb recess having a saddle fin structure;
forming a gate insulating layer over the surface of the resultant structure including the bulb recess; and
forming a gate electrode over the gate insulating layer such that the gate electrode is filled into the bulb recess and covers the device isolation structure exposed by the opening.

10. The method of claim 9, wherein the forming of the opening comprises:
forming a mask that simultaneously opens the channel-forming region of the active region and a portion of the device isolation structure over the substrate in a line shape; and
selectively etching the device isolation structure using the mask as an etch barrier.

11. The method of claim 9, wherein the forming of the bulb recess comprises:
etching the channel-forming region of the active region exposed by the opening to form a neck pattern having sidewalls;
forming a spacer over the sidewalls of the neck pattern; and
etching the bottom of the neck pattern into a round profile to form a ball pattern.

12. The method of claim 11, wherein forming further comprises forming the spacer comprising nitride.

13. The method of claim 11, wherein etching the bottom of the neck pattern further comprises isotropic etching.

14. The method of claim 9, wherein the depth of the opening is deeper than the bottom surface of the bulb recess by at least 150 Å.
